(19) United States
(12) Patent Application Publication
(10) Pub. No.: US 2020/0292580 A1
(43) Pub. Date: Sep. 17, 2020

(54) METHOD FOR MANUFACTURING PROBES

(71) Applicant: MPI Corporation, Hsinchu County (TW)

(72) Inventors: Chia-Ju WEI, Hsinchu County (TW); Tzu-Yang CHEN, Hsinchu County (TW)

(21) Appl. No.: 16/730,973

(22) Filed: Dec. 30, 2019

(30) Foreign Application Priority Data
Mar. 11, 2019 (TW) 108108088

(51) Int. Cl. G01R 1/073; B23C 3/13; B24C 1/04; B23K 26/38

(52) U.S. Cl. CPC G01R 1/07342; B23C 3/13; B23C 2220/36; B23K 26/38; B24C 1/045

(57) ABSTRACT

A method for manufacturing probes includes forming a recessed portion on a plate such that the plate has a first subsidiary plate, a second subsidiary plate and a third subsidiary plate mutually connected. The first subsidiary plate has a first thickness. The second subsidiary plate corresponds to the recessed portion and has a second thickness. The first thickness is larger than the second thickness. The second subsidiary plate is located between the first subsidiary plate and the third subsidiary plate. The third subsidiary plate has a third thickness. The third thickness is larger than the second thickness. Subsequently, the plate is held and cut by laser to form a plurality of probes. Each of the probes includes a probe tail formed from the first subsidiary plate, a probe body formed from the second subsidiary plate and a probe tip formed form the third subsidiary plate.

### RELATED APPLICATIONS

This application claims priority to Taiwanese Application Serial Number 108108088 filed Mar. 11, 2019, which is herein incorporated by reference.

### BACKGROUND

### Technical Field

The present disclosure relates to methods for manufacturing probes.

### Description of Related Art

The main function of a probe card is to directly contact with the welding pads or bumps on a device under test (such as a wafer, a chip or a die) with its probe, in order to achieve the purpose of testing the device under test with the configuration of a tester or software control, such that defective products can be screened. In general, a testing signal is generated from the tester, and the testing signal reaches the device under test through the probe card. Afterwards, a signal of testing result is transmitted back to the tester through the probe card for analysis.

Generally speaking, the probe card is equipped with a probe head in order to fix a certain number of probes. During testing, the device under test is held on a tester, and a number of probes contact with the device under test at the same time.

### SUMMARY

A technical aspect of the present disclosure is to provide a method for manufacturing probes which can produce a plurality of probes from a plate by laser cutting in order to reduce the cost of production.

According to an embodiment of the present disclosure, a method for manufacturing probes is provided. The manufacturing method includes forming at least one recessed portion on a plate such that the plate has a first subsidiary plate, a second subsidiary plate and a third subsidiary plate mutually connected along a first direction. The first subsidiary plate has a first thickness along a second direction. The second direction is perpendicular to the first direction. The second subsidiary plate corresponds to the recessed portion and has a second thickness along the second direction. The first thickness is larger than the second thickness. The second subsidiary plate is located between the first subsidiary plate and the third subsidiary plate. The third subsidiary plate has a third thickness along the second direction. The third thickness is larger than the second thickness. Subsequently, the plate is held and cut by laser to form a plurality of probes. Each of the probes includes a probe tail formed from the first subsidiary plate, a probe body formed from the second subsidiary plate and a probe tip formed form the third subsidiary plate. A width of the probe body along a third direction is larger than a width of the probe tip and the probe tail along the third direction. The third direction is perpendicular to the first direction and the second direction.

According to an embodiment of the present disclosure, a method for manufacturing probes is provided. The manufacturing method includes forming a plurality of recessed portions on a plate such that the plate has a first subsidiary plate, a second subsidiary plate and a third subsidiary plate mutually connected along a first direction. The first subsidiary plate has a first thickness along a second direction. The second direction is perpendicular to the first direction. The first subsidiary plate and the third subsidiary plate respectively correspond to the recessed portions. The second subsidiary plate has a second thickness along the second direction. The second thickness is larger than the first thickness. The second subsidiary plate is located between the first subsidiary plate and the third subsidiary plate. The third subsidiary plate has a third thickness along the second direction. The third thickness is smaller than the second thickness. Subsequently, the plate is held and cut by laser to form a plurality of probes. Each of the probes includes a probe tail formed from the first subsidiary plate, a probe body formed from the second subsidiary plate and a probe tip formed form the third subsidiary plate.

### BRIEF DESCRIPTION OF THE DRAWINGS

The disclosure can be more fully understood by reading the following detailed description of the embodiments, with reference made to the accompanying drawings as follows:

FIG. 1 is a flow diagram of a manufacturing method of probes according to an embodiment of the present disclosure;

FIG. 2 is a top view of the plate of FIG. 1;

FIG. 3 is a schematic view of the plate of FIG. 1;

FIG. 4 is a schematic view of a plurality of finished products cut from the plate of FIG. 3 by laser;

FIG. 5 is a top view of a plate according to another embodiment of the present disclosure;

FIG. 6 is a schematic view of the plate of FIG. 5;

FIG. 7 is a schematic view of a plurality of finished products cut from the plate of FIG. 6 by laser;

FIG. 8 is a schematic view of a plate according to a further embodiment of the present disclosure;

FIG. 9 is a schematic view of a plurality of finished products cut from the plate of FIG. 8 by laser;

FIG. 10 is a flow diagram of a manufacturing method of probes according to another embodiment of the present disclosure;

FIG. 11 is a top view of the plate of FIG. 10;

FIG. 12 is a schematic view of the plate of FIG. 11;

FIG. 13 is a schematic view of a plurality of finished products cut from the plate of FIG. 12 by laser;

FIG. 14 is a top view of a plate according to another embodiment of the present disclosure;

FIG. 15 is a schematic view of the plate of FIG. 14;

FIG. 16 is a schematic view of a plurality of finished products cut from the plate of FIG. 15 by laser;

FIG. 17 is a schematic view of a plate according to a further embodiment of the present disclosure;

FIG. 18 is a schematic view of a plurality of finished products cut from the plate of FIG. 17 by laser;

FIG. 19 is a schematic view of a plate according to another embodiment of the present disclosure;

FIG. 20 is a schematic view of a plurality of finished products cut from the plate of FIG. 19 by laser;

FIG. 21 is a schematic view of a plate according to a further embodiment of the present disclosure;

FIG. 22 is a schematic view of a plurality of finished products cut from the plate of FIG. 21 by laser;

FIG. 23 is a schematic view of a plate according to another embodiment of the present disclosure;

FIG. 24 is a schematic view of a plurality of finished products cut from the plate of FIG. 23 by laser;

FIG. 25 is a schematic view of a plate according to a further embodiment of the present disclosure; and

FIG. 26 is a schematic view of a plurality of finished products cut from the plate of FIG. 25 by laser.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

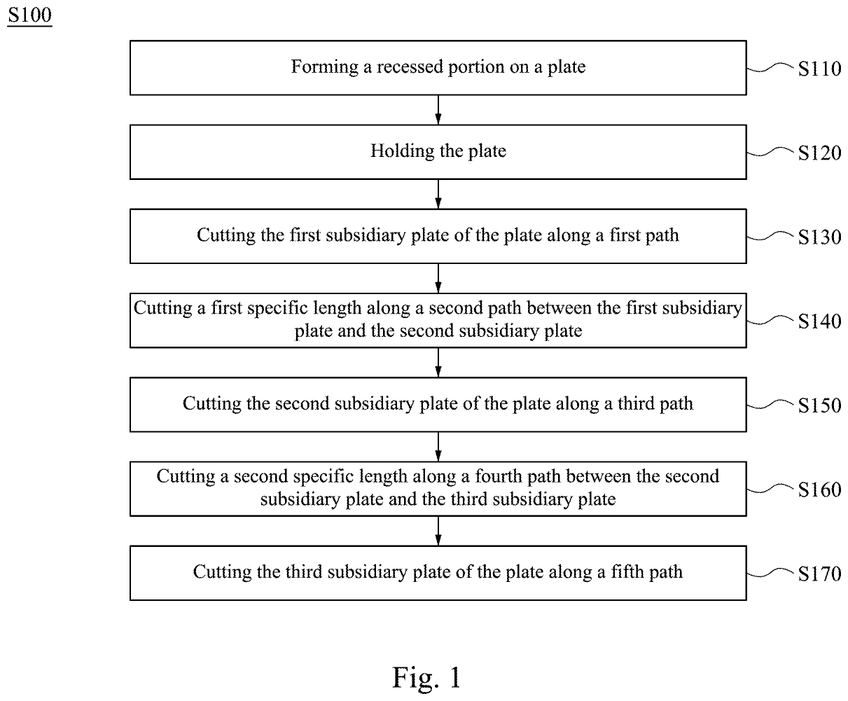

Reference is made to FIG. 1. FIG. 1 is a flow diagram of a manufacturing method of probes S100 according to an embodiment of the present disclosure. As shown in FIG. 1, the manufacturing method of probes S100 includes the following procedures (it should be noted that the sequence of the procedures and the subsidiary procedures as mentioned below, unless otherwise specified, can all be adjusted upon the actual needs, or even executed at the same time or partially at the same time):

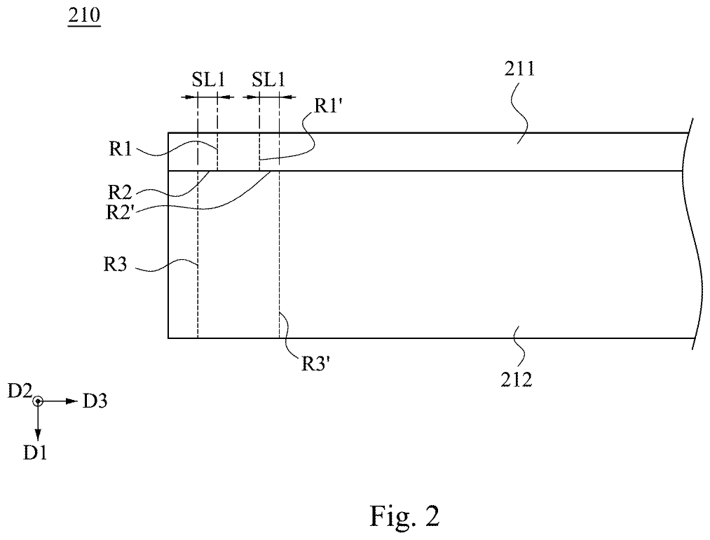

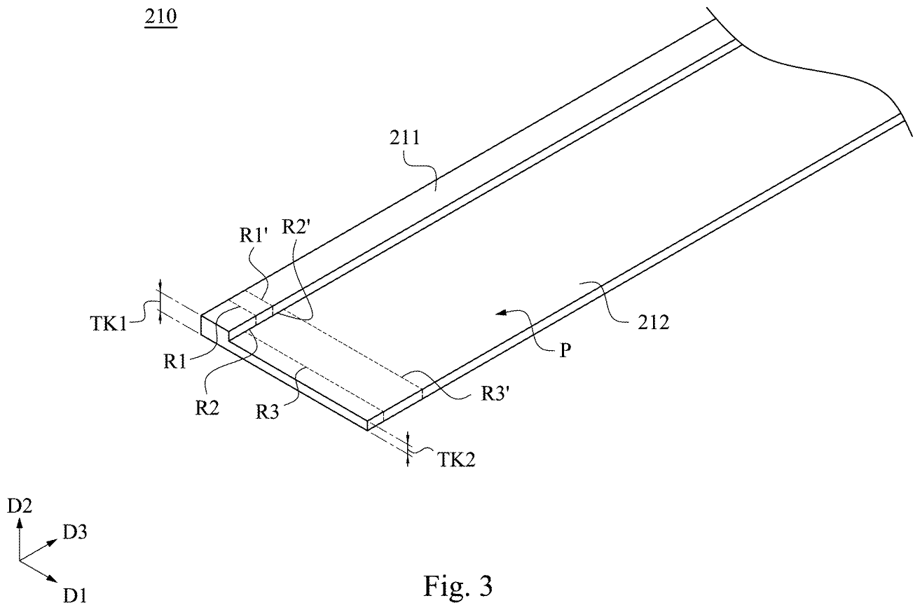

(1) Forming a recessed portion P on a plate 210 (Procedure S110). Reference is made to FIGS. 2-3. FIG. 2 is a top view of the plate 210 of FIG. 1. FIG. 3 is a schematic view of the plate 210 of FIG. 1. To specific, as shown in FIGS. 2-3, the plate 210 forming the recessed portion P has a first subsidiary plate 211 and a second subsidiary plate 212 mutually connected along a first direction D1. The first subsidiary plate 211 has a first thickness TK1 along a second direction D2. The second direction D2 is perpendicular to the first direction D1. The second subsidiary plate 212 corresponds to the recessed portion P and has a second thickness TK2 along the second direction D2. The first thickness TK1 is larger than the second thickness TK2. In other words, the first subsidiary plate 211 of the plate 210 is thicker than the second subsidiary plate 212.

(2) Holding the plate 210 on a machine (not shown) (Procedure S120).

(3) Cutting the plate 210 by laser, for example, cutting the first subsidiary plate 211 of the plate 210 along a first path R1 (Procedure S130). In this embodiment, as shown in FIGS. 2-3, the first path R1 is parallel with the first direction D1, and the first path R1 stops at the junction between the first subsidiary plate 211 and the second subsidiary plate 212.

(4) Cutting a first specific length SL1 along a second path R2 between the first subsidiary plate 211 and the second subsidiary plate 212 by laser (Procedure S140). In this embodiment, as shown in FIGS. 2-3, the second path R2 is parallel with a third direction D3. The third direction D3 is perpendicular to the first direction D1 and the second direction D2. To be specific, the second path R2 is connected with the first path R1. In other words, the laser cutting along the second path R2 can substantially follow the laser cutting along the first path R1 continuously.

(5) Cutting the second subsidiary plate 212 of the plate 210 along a third path R3 (Procedure S150). In this embodiment, as shown in FIGS. 2-3, the third path R3 is parallel with the first direction D1, and is staggered from the first path R1 by the first specific length SL1. To be specific, the third path R3 is connected with the second path R2. In other words, the laser cutting along the third path R3 can substantially follow the laser cutting along the second path R2 continuously. This means, the laser cutting of the plate 210 can be carried out continuously along the first path R1, the second path R2 and the third path R3.

In this way, in this embodiment, with regard to different thicknesses of the plate 210, namely the first thickness TK1 and the second thickness TK2 as mentioned above, the user can adopt mutually connected paths for laser cutting, which are the first path R1, the second path R2 and the third path R3 as mentioned above, in order to carry out laser cutting to the plate 210 in a convenient manner.

In addition, as shown in FIGS. 2-3, the user can cut the plate 210 by laser along a first path R1′, a second path R2′ and a third path R3′ based on the method mentioned above. It is worth to note that, the second path R2 and the second path R2′ extend towards opposite directions. The length of laser cutting along the second path R2′ can be equal to the first specific length SL1. However, this does not intend to limit the present disclosure.

In practical applications, the procedure as mentioned above to form the recessed portion P on the plate 210 can adopt but not limit to the following three processing methods of non-laser cutting:

(1.1) Covering a photoresist material (not shown) on a position of plate 210 corresponding to the first subsidiary plate 211, and carrying out wet etching to the plate 210. As blocked by the photoresist material, the portion of the first subsidiary plate 211 is not etched by the etching solution. On the contrary, the portion not covered by the photoresist material, i.e., the portion corresponding to the second subsidiary plate 212, is etched by the etching solution, such that the plate 210 forms the recessed portion P at the position corresponding to the second subsidiary plate 212. Subsequently, the photoresist material is removed.

(1.2) Removing a portion of the plate 210 corresponding to the position of the second subsidiary plate 212 by mechanical cutting, such that the plate 210 forms the recessed portion P at the position corresponding to the second subsidiary plate 212. To be specific, the mechanical cutting can be milling. However, this does not intend to limit the present disclosure.

(1.3) Sand blasting a surface of the plate 210 corresponding to the second subsidiary plate 212, such that the plate 210 forms the recessed portion P at the position corresponding to the second subsidiary plate 212.

In sum, the processing methods of non-laser cutting as mentioned above process on the plate 210 in the second direction D2, such that the plate 210 appears as regions of the first subsidiary plate 211 and the second subsidiary plate 212 with different thicknesses. That is, through the processing methods of non-laser cutting as mentioned above, the probes are first processed in the second direction D2, so as to meet the requirement of appearance of the probes in the second direction D2 (i.e., formation of the recessed portion P). Meanwhile, the technique of laser cutting as mentioned above processes to the plate 210 in the first direction D1 and the third direction D3, so as to meet the requirement of appearance of the probes in the first direction D1 and the third direction D3. Thus, the present disclosure can define and manufacture three-dimensional finished products 250 from the plate 210. Moreover, the finished products 250 can be used as probes to be installed at a probe head (not shown). In this way, through the combination of the processing methods of non-laser cutting and the technique of laser cutting, the probes can be manufactured in a simple and easy manner. In addition, the application of laser cutting can decrease the error rate of processing between the probes.

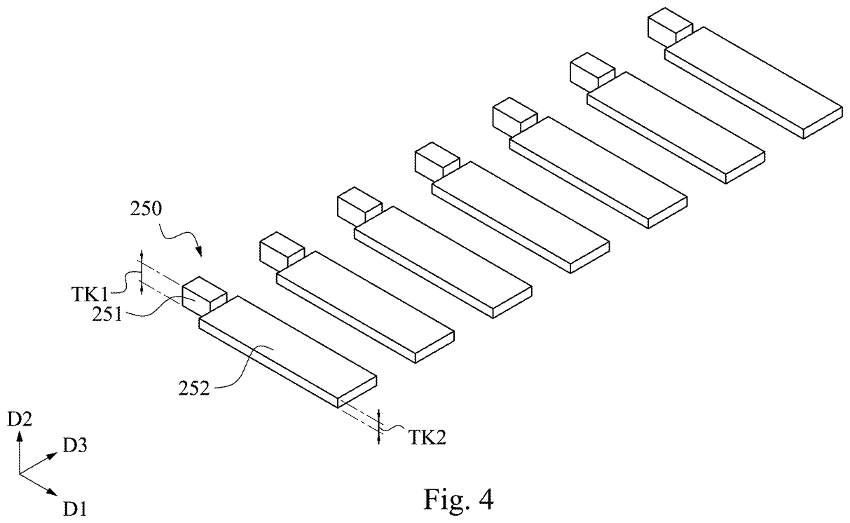

On the other hand, reference is made to FIG. 4. FIG. 4 is a schematic view of a plurality of finished products 250 cut from the plate 210 of FIG. 3 by laser. In this embodiment, through the simple and convenient method of laser cutting as mentioned above, the user can produce a finished product 250 from the plate 210 through laser cutting. By repeating the procedures as mentioned above, as shown in FIG. 4, the user can efficiently produce a plurality of finished products 250 from the plate 210 through laser cutting.

In practical applications, as mentioned above, the finished products 250 can be used as probes to be installed at the probe head. The portion of each of the finished products 250 originally formed from the first subsidiary plate 211, which is the probe tail of a probe for example, can be snapped to the probe head as a stopping structure 251. The portion of each of the finished products 250 originally formed from the second subsidiary plate 212 can be used as the probe body 252 of a probe.

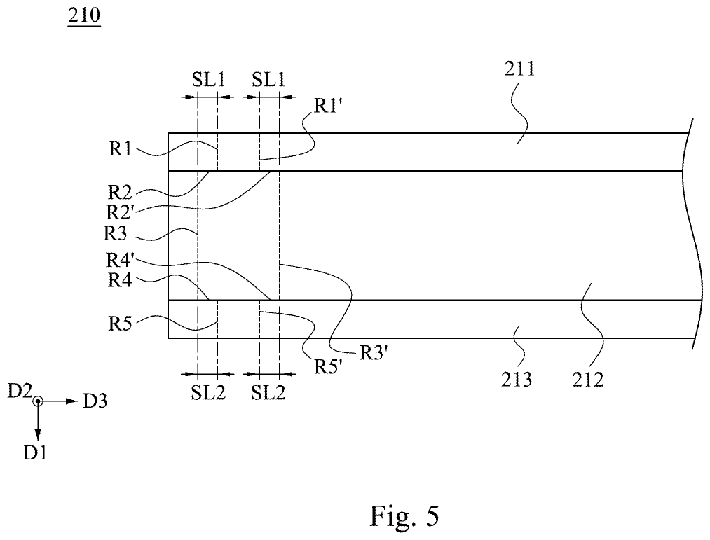

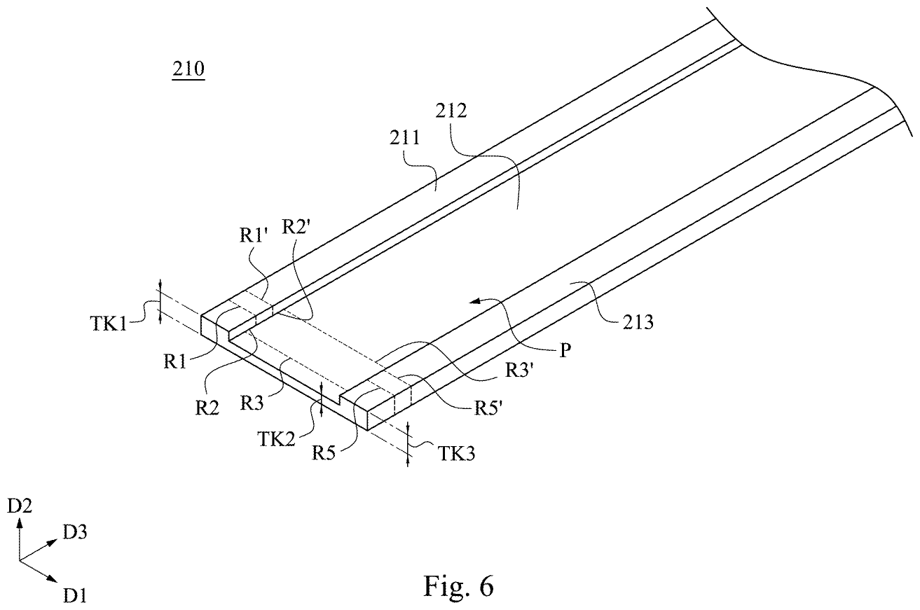

Reference is made to FIGS. 5-6. FIG. 5 is a top view of a plate 210 according to another embodiment of the present disclosure. FIG. 6 is a schematic view of the plate 210 of FIG. 5. In this embodiment, as shown in FIGS. 5-6, the plate 210 further includes a third subsidiary plate 213. The second subsidiary plate 212 is located between the first subsidiary plate 211 and the third subsidiary plate 213. The third subsidiary plate 213 has a third thickness TK3 along the second direction D2. The third thickness TK3 is larger than the second thickness TK2. In other words, the third subsidiary plate 213 of the plate 210 is thicker than the second subsidiary plate 212.

In this embodiment, the manufacturing method of probes S100 further includes the following procedures (it should be noted that the sequence of the procedures and the subsidiary procedures as mentioned below, unless otherwise specified, can all be adjusted upon the actual needs, or even executed at the same time or partially at the same time):

(6) Cutting a second specific length SL2 along a fourth path R4 between the second subsidiary plate 212 and the third subsidiary plate 213 by laser (Procedure S160). In this embodiment, as shown in FIGS. 5-6, the fourth path R4 is parallel with the third direction D3, and the fourth path R4 is connected with the third path R3. In other words, the laser cutting along the fourth path R4 can substantially follow the laser cutting along the third path R3 continuously.

(7) Cutting the third subsidiary plate 213 of the plate 210 along a fifth path R5 (Procedure S170). In this embodiment, as shown in FIGS. 5-6, the fifth path R5 is parallel with the first direction D1, and the fifth path R5 is connected with the fourth path R4. In other words, the laser cutting along the fifth path R5 can substantially follow the laser cutting along the fourth path R4 continuously.

In addition, as shown in FIGS. 5-6, the user can cut the plate 210 by laser along a fourth path R4′ and a fifth path R5′ based on the method mentioned above. It is worth to note that, the fourth path R4 and the fourth path R4′ extend towards opposite directions. The length of laser cutting along the fourth path R4′ can be equal to the second specific length SL2. However, this does not intend to limit the present disclosure.

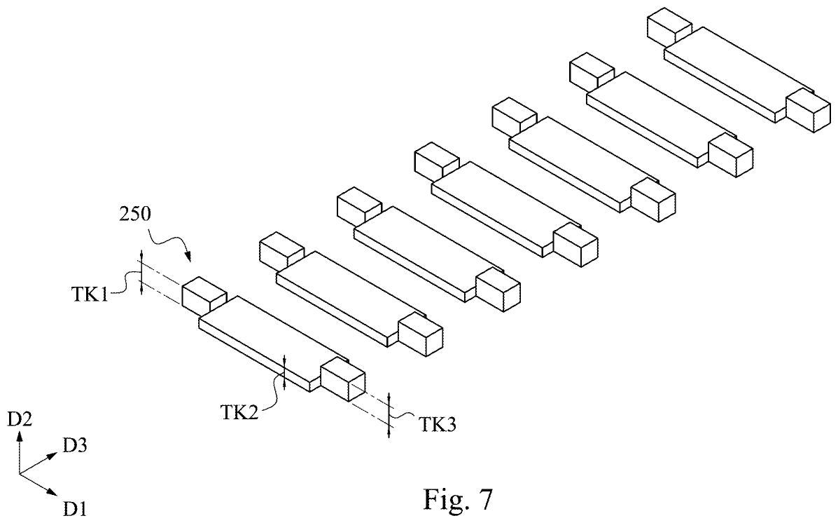

Reference is made to FIG. 7. FIG. 7 is a schematic view of a plurality of finished products 250 cut from the plate 210 of FIG. 6 by laser. In this embodiment, through the simple and convenient method of laser cutting as mentioned above, the user can produce a finished product 250 from the plate 210 through laser cutting. By repeating the procedures as mentioned above, as shown in FIG. 7, the user can efficiently produce a plurality of finished products 250 from the plate 210 through laser cutting. Similarly, the finished products 250 can be used as probes to be installed at the probe head. It is worth to note that, in practical applications, the first subsidiary plate 211, the second subsidiary plate 212 and the third subsidiary plate 213 of the plate 210 at least have a common plane perpendicular to the second direction D2, such that a cross-section of the plate 210 perpendicular to the third direction D3 can form a “U” shape. Moreover, each of the finished products 250 in this embodiment also has a side surface in a “U” shape.

Furthermore, according to the actual requirements for the finished products 250, the second specific length SL2 can be the same as the first specific length SL1, such that the portion of each of the finished products 250 originally formed from the first subsidiary plate 211, which is the probe tail of a probe for example, and the portion of each of the finished products 250 originally formed from the third subsidiary plate 213, which is the probe tip of a probe for example, have the same widths in the third direction D3. On the other hand, according to the actual requirements for the finished products 250, the second specific length SL2 can be different from the first specific length SL1, such that the portion of each of the finished products 250 originally formed from the first subsidiary plate 211, which is the probe tail of a probe for example, and the portion of each of the finished products 250 originally formed from the third subsidiary plate 213, which is the probe tip of a probe for example, have different widths in the third direction D3.

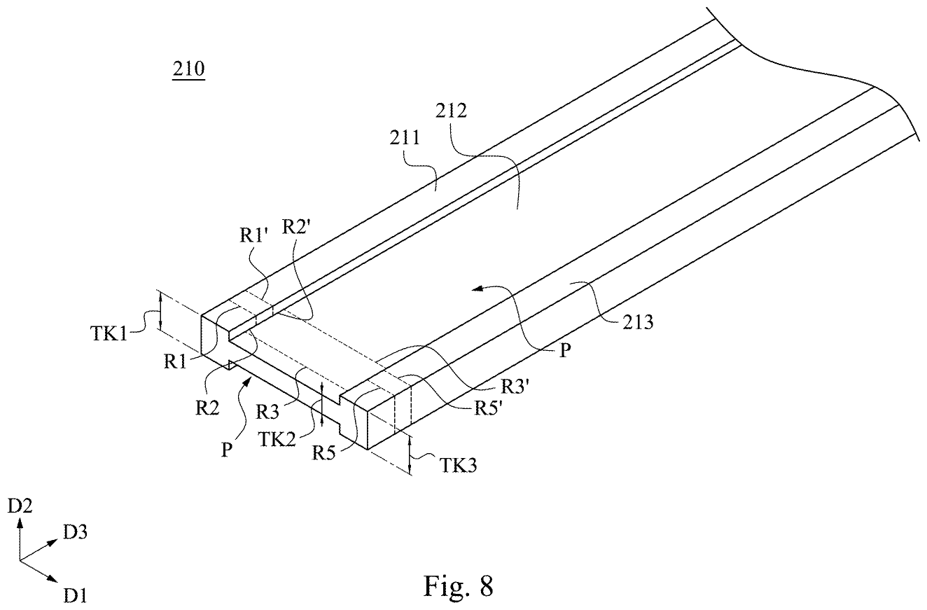

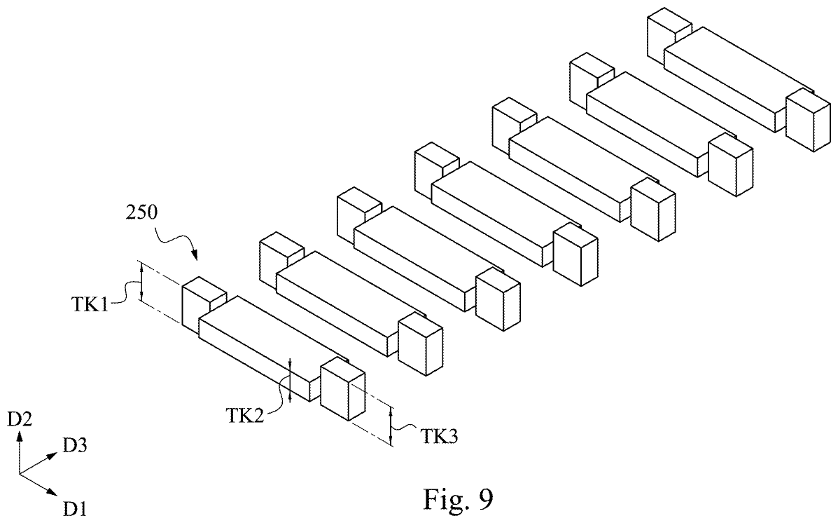

Reference is made to FIGS. 8-9. FIG. 8 is a schematic view of a plate 210 according to a further embodiment of the present disclosure. FIG. 9 is a schematic view of a plurality of finished products 250 cut from the plate 210 of FIG. 8 by laser. In this embodiment, as shown in FIGS. 8-9, the first subsidiary plate 211, the second subsidiary plate 212 and the third subsidiary plate 213 of the plate 210 do not have a common plane perpendicular to the second direction D2, such that a cross-section of the plate 210 perpendicular to the third direction D3 can form a “H” shape. Moreover, each of the finished products 250 in this embodiment also has a side surface in a “H” shape. Moreover, through the paths R1, R2, R3, R4, R5, R1′, R2′, R3′, R4′, R5′ of laser cutting as mentioned above, the central portion of each of the finished products 250, which is the probe body for example, has a wider width in the third direction D3. This means, the distance between the third paths R3, R3′ is larger than the distance between the first paths R1, R1′, and is larger than the distance between the fifth paths R5, R5′. Therefore, as viewed from the second direction D2, each of the finished products 250 has a “+” shape.

In addition, in this embodiment, as shown in FIGS. 8-9, the distance between the third paths R3, R3′ is larger than the second thickness TK2. Therefore, when the two ends of each of the finished products 250 are compressed towards each other, the central portion tends to bend about the third direction D3, which is understood as bending towards the second direction D2. In this way, when a plurality of finished products 250 are used as probes to be installed at the probe head, and the two ends of each of the probes are compressed towards each other at the same time, the probes will bend about the third direction D3, such that the condition that the probes touch with each other because of bending due to compression is avoided.

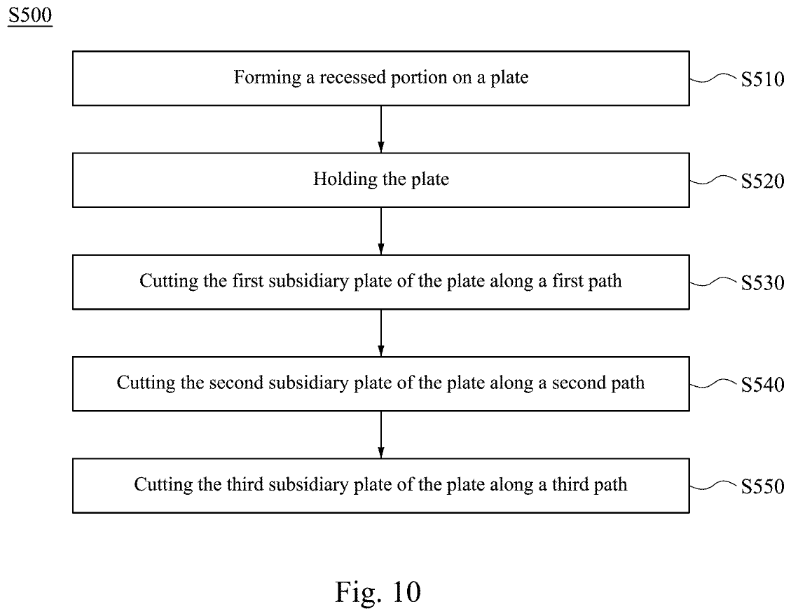

Reference is made to FIG. 10. FIG. 10 is a flow diagram of a manufacturing method of probes S500 according to another embodiment of the present disclosure. As shown in FIG. 10, the manufacturing method of probes S500 includes the following procedures (it should be noted that the sequence of the procedures and the subsidiary procedures as mentioned below, unless otherwise specified, can all be adjusted upon the actual needs, or even executed at the same time or partially at the same time):

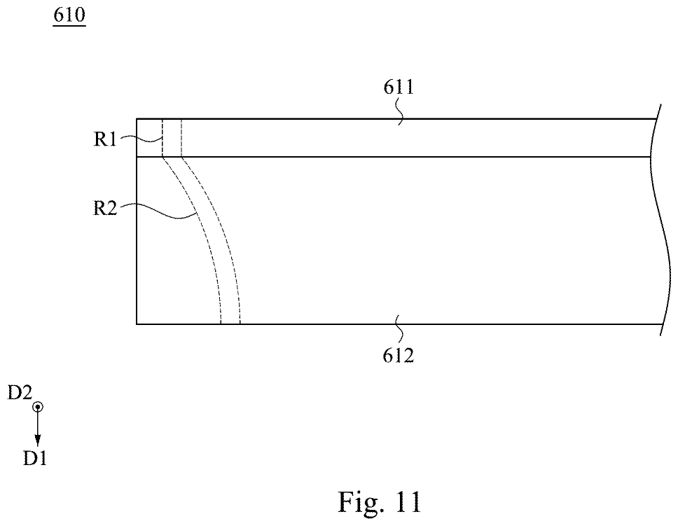

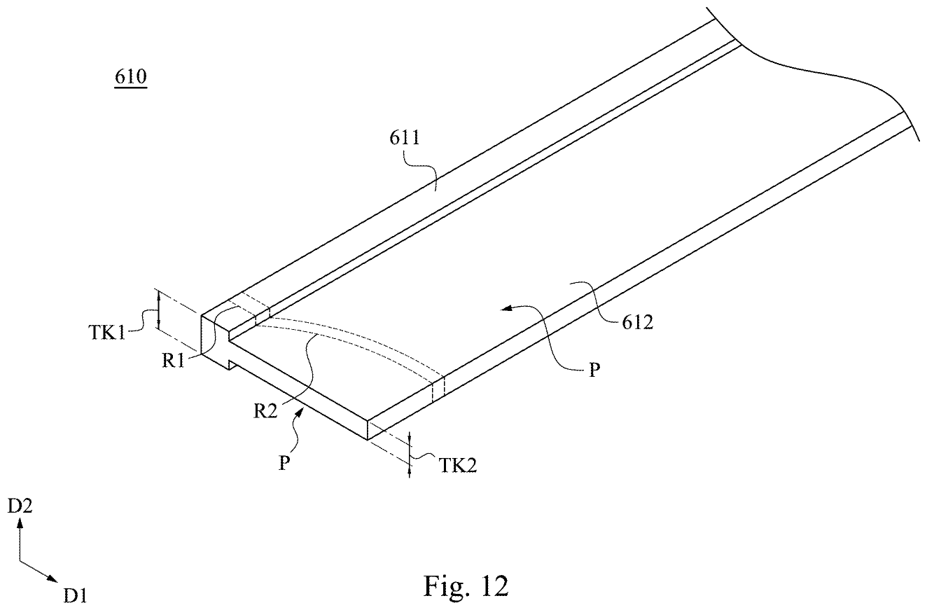

(1) Forming a recessed portion P on a plate 610 (Procedure S510). Reference is made to FIGS. 11-12. FIG. 11 is a top view of the plate 610 of FIG. 10. FIG. 12 is a schematic view of the plate 610 of FIG. 11. To be specific, as shown in FIGS. 11-12, the plate 610 has a first subsidiary plate 611 and a second subsidiary plate 612 mutually connected along a first direction D1. The first subsidiary plate 611 has a first thickness TK1 along a second direction D2. The second direction D2 is perpendicular to the first direction D1. The second subsidiary plate 612 has a second thickness TK2 along the second direction D2. The first thickness TK1 is different from the second thickness TK2. For example, in this embodiment, the first subsidiary plate 611 of the plate 610 is thicker than the second subsidiary plate 612, and the second subsidiary plate 612 corresponds to the recessed portion P.

(2) Holding the plate 610 on a machine (not shown) (Procedure S520).

(3) Cutting the plate 610 by laser, for example, cutting the first subsidiary plate 611 of the plate 610 along a first path R1 (Procedure S530). In this embodiment, as shown in FIGS. 11-12, the first path R1 is parallel with the first direction D1.

(4) Cutting the second subsidiary plate 612 of the plate 610 along a second path R2 by laser (Procedure S540). In this embodiment, as shown in FIGS. 11-12, the second path R2 is a curved path. To be specific, the second path R2 is connected with the first path R1. In other words, the laser cutting along the second path R2 can substantially follow the laser cutting along the first path R1 continuously.

In this way, in this embodiment, with regard to different thicknesses of the plate 610, namely the first thickness TK1 and the second thickness TK2 as mentioned above, the user can adopt mutually connected paths for laser cutting, which are the first path R1 and the second path R2 as mentioned above, in order to carry out laser cutting to the plate 610 in a simple and convenient manner.

In practical applications, the procedure as mentioned above to form the recessed portion P on the plate 610 can adopt but not limit to the following three processing methods of non-laser cutting:

(1.1) Covering a photoresist material (not shown) on a position of plate 610 corresponding to the first subsidiary plate 611, and carrying out wet etching to the plate 610. As blocked by the photoresist material, the portion of the first subsidiary plate 611 is not etched by the etching solution. On the contrary, the portion not covered by the photoresist material, i.e., the portion corresponding to the second subsidiary plate 612, is etched by the etching solution, such that the plate 610 forms the recessed portion P at the position corresponding to the second subsidiary plate 612. Subsequently, the photoresist material is removed.

(1.2) Removing a portion of the plate 610 corresponding to the position of the second subsidiary plate 612 by mechanical cutting, such that the plate 610 forms the recessed portion P at the position corresponding to the second subsidiary plate 612. To be specific, the mechanical cutting can be milling. However, this does not intend to limit the present disclosure.

(1.3) Sand blasting a surface of the plate 610 corresponding to the second subsidiary plate 612, such that the plate 610 forms the recessed portion P at the position corresponding to the second subsidiary plate 612.

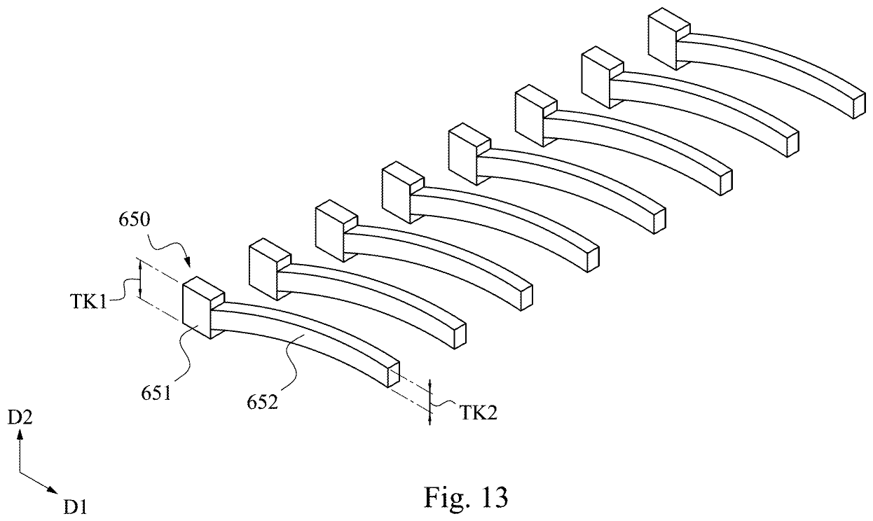

On the other hand, reference is made to FIG. 13. FIG. 13 is a schematic view of a plurality of finished products 650 cut from the plate 610 of FIG. 12 by laser. In this embodiment, through the simple and convenient method of laser cutting as mentioned above, the user can produce a finished product 650 from the plate 610 through laser cutting. By repeating the procedures as mentioned above, as shown in FIG. 13, the user can efficiently produce a plurality of finished products 650 from the plate 610 through laser cutting.

In practical applications, as mentioned above, the finished products 650 can be used as probes to be installed at a probe head. The portion of each of the finished products 650 originally formed from the first subsidiary plate 611, which is the probe tail of a probe for example, can be snapped to the probe head as a stopping structure 651. The portion of each of the finished products 650 originally formed from the second subsidiary plate 612 can be used as the probe body 652 of a probe.

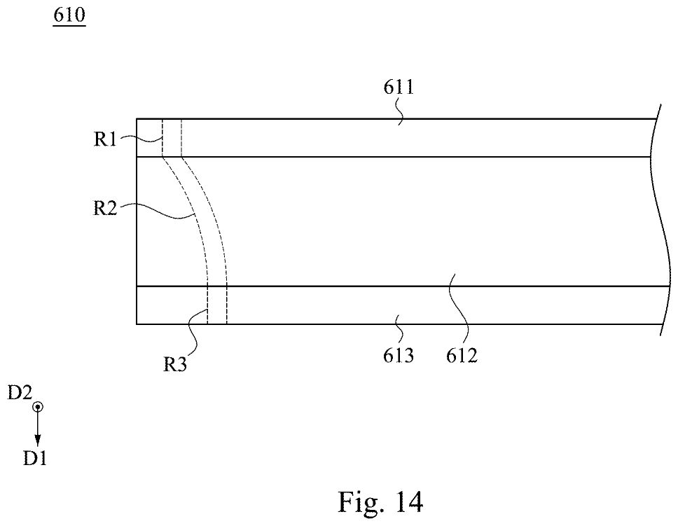

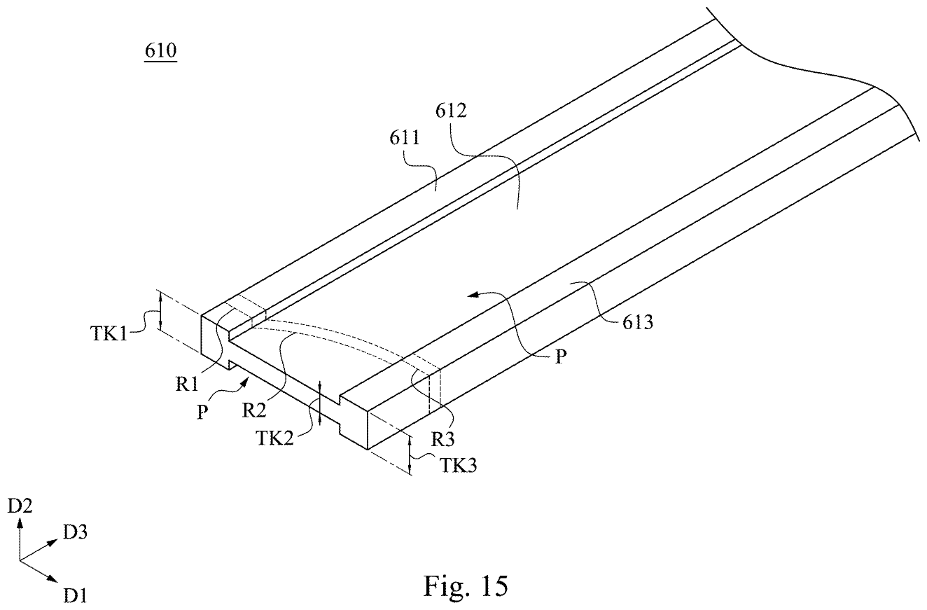

Reference is made to FIGS. 14-15. FIG. 14 is a top view of a plate 610 according to another embodiment of the present disclosure. FIG. 15 is a schematic view of the plate 610 of FIG. 14. In this embodiment, as shown in FIGS. 14-15, the plate 610 further includes a third subsidiary plate 613. The second subsidiary plate 612 is located between the first subsidiary plate 611 and the third subsidiary plate 613. The third subsidiary plate 613 has a third thickness TK3 along the second direction D2. The third thickness TK3 is different from the second thickness TK2. For example, in this embodiment, the second thickness TK2 is thinner than the first thickness TK1 and the third thickness TK3.

In this embodiment, the manufacturing method of probes S500 further includes the following procedures (it should be noted that the sequence of the procedures and the subsidiary procedures as mentioned below, unless otherwise specified, can all be adjusted upon the actual needs, or even executed at the same time or partially at the same time):

(5) Cutting the third subsidiary plate 613 of the plate 610 along a third path R3 (Procedure S550). In this embodiment, as shown in FIGS. 14-15, the third path R3 is parallel with the first direction D1, and is staggered from the first path R1. To be specific, the third path R3 is connected with the second path R2. In other words, the laser cutting along the third path R3 can substantially follow the laser cutting along the second path R2 continuously. This means, the laser cutting of the plate 610 can be carried out continuously along the first path R1, the second path R2 and the third path R3.

In this way, in this embodiment, with regard to different thicknesses of the plate 610, namely the first thickness TK1, the second thickness TK2 and the third thickness TK3 as mentioned above, the user can adopt mutually connected paths for laser cutting, which are the first path R1, the second path R2 and the third path R3 as mentioned above, in order to carry out laser cutting to the plate 610 in a simple and convenient manner.

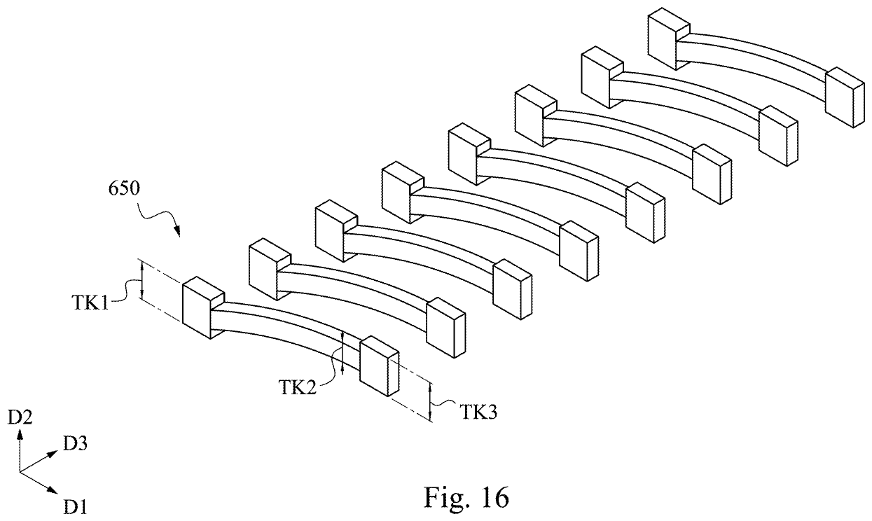

Reference is made to FIG. 16. FIG. 16 is a schematic view of a plurality of finished products 650 cut from the plate 610 of FIG. 15 by laser. In this embodiment, through the simple and convenient method of laser cutting as mentioned above, the user can produce a finished product 650 from the plate 610 through laser cutting. By repeating the procedures as mentioned above, as shown in FIG. 16, the user can efficiently produce a plurality of finished products 650 from the plate 610 through laser cutting.

In addition, in this embodiment, as shown in FIGS. 15-16, the first subsidiary plate 611, the second subsidiary plate 612 and the third subsidiary plate 613 of the plate 610 do not have a common plane perpendicular to the second direction D2. Moreover, as mentioned above, the second thickness TK2 is thinner than the first thickness TK1 and the third thickness TK3. Therefore, a cross-section of the plate 610 parallel with the first direction D1 and the second direction D2 can form a “H” shape. Moreover, each of the finished products 650 in this embodiment also has a side surface in a “H” shape.

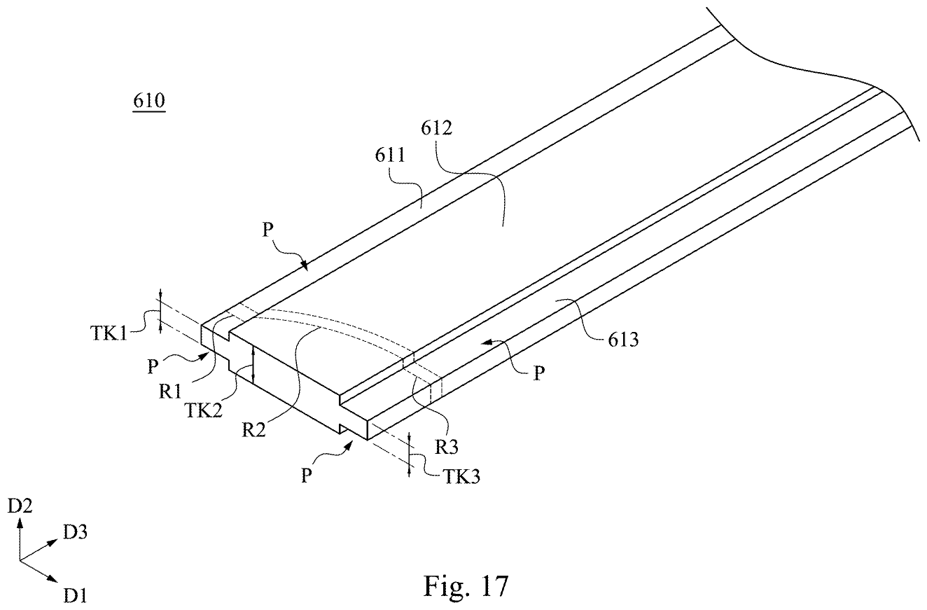

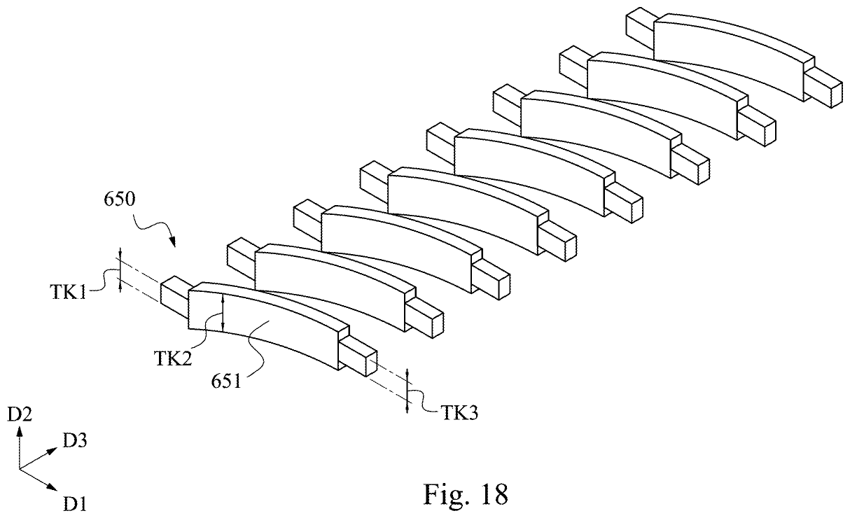

Reference is made to FIGS. 17-18. FIG. 17 is a schematic view of a plate 610 according to a further embodiment of the present disclosure. FIG. 18 is a schematic view of a plurality of finished products 650 cut from the plate 610 of FIG. 17 by laser. In this embodiment, as shown in FIGS. 17-18, the first subsidiary plate 611, the second subsidiary plate 612 and the third subsidiary plate 613 of the plate 610 do not have a common plane perpendicular to the second direction D2. Moreover, the second thickness TK2 is thicker than the first thickness TK1 and the third thickness TK3, i.e., the first subsidiary plate 611 and the third subsidiary plate 613 respectively correspond to the recessed portions P, such that a cross-section of the plate 610 parallel with the first direction D1 and the second direction D2 can form a “+” shape. Moreover, each of the finished products 650 in this embodiment also has a side surface in a “+” shape. In this way, the portion of each of the finished products 650 originally formed from the second subsidiary plate 612 can be snapped to the probe head as a stopping structure 651. To be specific, each of the probes includes a probe tail formed from the first subsidiary plate 611, a probe body formed from the second subsidiary plate 612 and a probe tip formed form the third subsidiary plate 613. Through the laser cutting of the second subsidiary plate 612 along curved paths, the bending direction of the probes can be effectively predetermined, such that the condition that the probes touch and collide with each other is avoided.

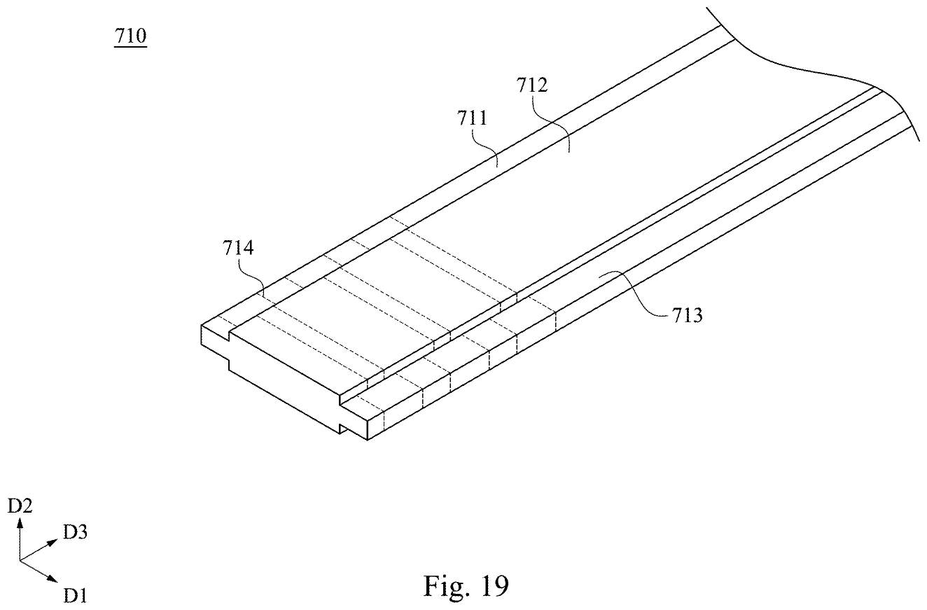

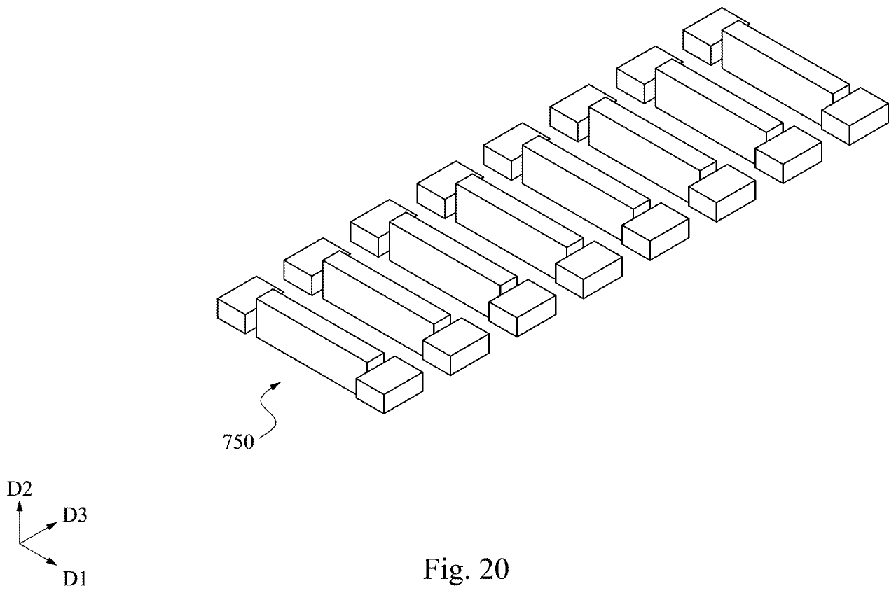

Reference is made to FIGS. 19-20. FIG. 19 is a schematic view of a plate 710 according to another embodiment of the present disclosure. FIG. 20 is a schematic view of a plurality of finished products 750 cut from the plate 710 of FIG. 19 by laser. As shown in FIGS. 19-20, the plate 710 is formed with recessed portions respectively at the first subsidiary plate 711 and the third subsidiary 713. The recessed portions are respectively located at the two sides of the first subsidiary plate 711 and the third subsidiary 713. Relatively, the second subsidiary plate 712 in the middle has a thicker thickness in the second direction D2. After being cut along the cutting path 714 by laser, the finished product 750 can be formed, such that the first subsidiary plate 711 is formed as the probe tail of a probe, the second subsidiary plate 712 is formed as the probe body of a probe, and the third subsidiary plate 713 is formed as the probe tip of a probe. The probe is bent around a predetermined direction. For example, the direction of bending is determined by the difference between the thickness and the width of the probe body, such that the bending direction of the probes can be effectively predetermined and the condition that the probes touch and collide with each other is avoided.

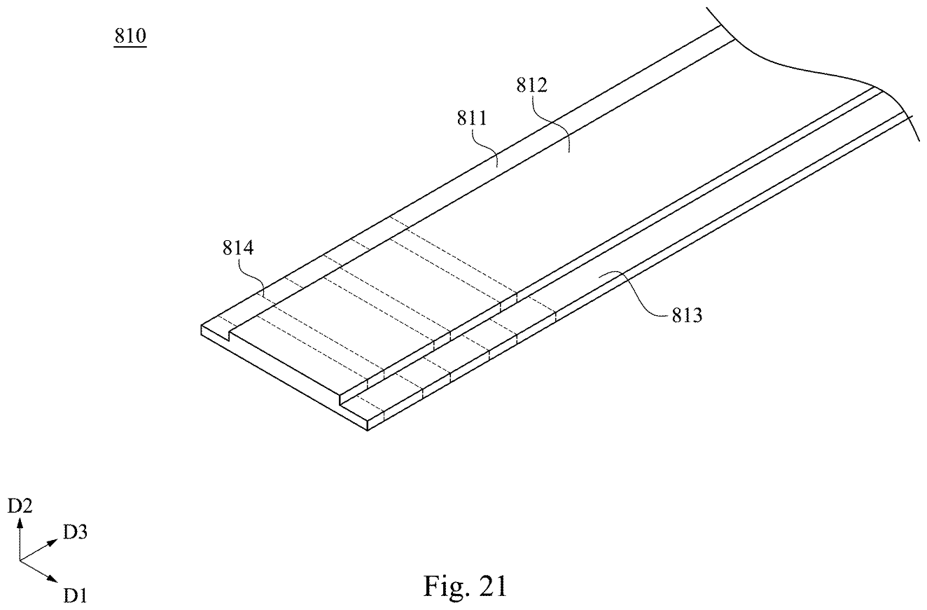

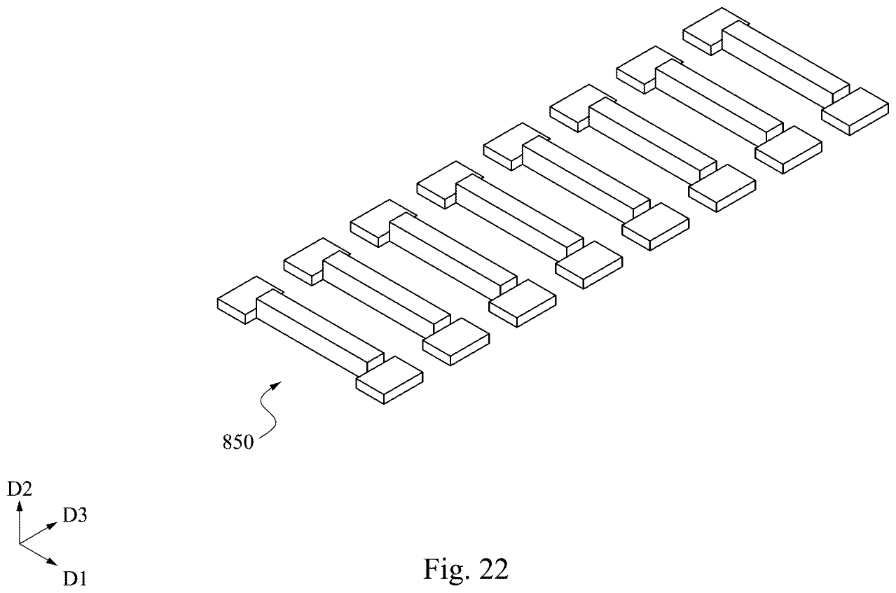

Reference is made to FIGS. 21-22. FIG. 21 is a schematic view of a plate 810 according to a further embodiment of the present disclosure. FIG. 22 is a schematic view of a plurality of finished products 850 cut from the plate 810 of FIG. 21 by laser. As shown in FIGS. 21-22, the plate 810 is formed with recessed portions respectively at a single side of the first subsidiary plate 811 and the third subsidiary 813. Relatively, the second subsidiary plate 812 in the middle has a thicker thickness in the second direction D2. After being cut along the cutting path 814 by laser, the finished product 850 can be formed, such that the first subsidiary plate 811 is formed as the probe tail of a probe, the second subsidiary plate 812 is formed as the probe body of a probe, and the third subsidiary plate 813 is formed as the probe tip of a probe. The probe is bent around a predetermined direction. For example, the direction of bending is determined by the difference between the thickness and the width of the probe body, such that the bending direction of the probes can be effectively predetermined and the condition that the probes touch and collide with each other is avoided.

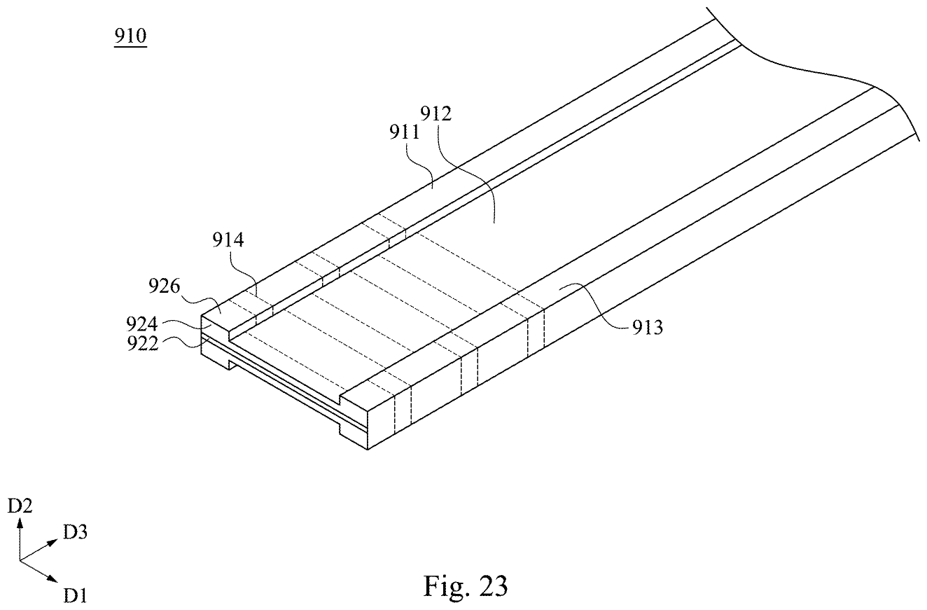

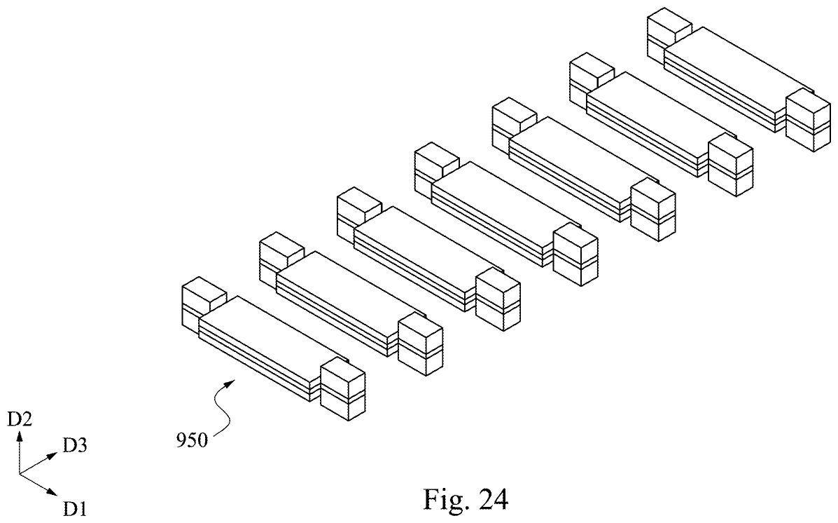

Reference is made to FIGS. 23-24. FIG. 23 is a schematic view of a plate 910 according to another embodiment of the present disclosure. FIG. 24 is a schematic view of a plurality of finished products 950 cut from the plate 910 of FIG. 23 by laser. As shown in FIGS. 23-24, the plate 910 is formed with recessed portions at the two sides of the second subsidiary plate 912. Relatively, the first subsidiary plate 911 and the third subsidiary plate 913 have a thicker thickness than the second subsidiary plate 912 in the middle. After being cut along the cutting path 914 by laser, the finished product 950 can be formed, such that the first subsidiary plate 911 is formed as the probe tail of a probe, the second subsidiary plate 912 is formed as the probe body of a probe, and the third subsidiary plate 913 is formed as the probe tip of a probe. The probe is bent around a predetermined direction, such as bending around the third direction D3. The bending direction of the probes can be effectively predetermined and the condition that the probes touch and collide with each other is avoided.

The plate 910 is a composite material plate formed from, for example, a core material 922, an inner cladding layer 924 formed around the core material 922 and a protective layer 926 formed on the surface of the inner cladding layer 924.

In some embodiments, the core material 922 can be formed from nickel, tungsten, cobalt, palladium or alloys thereof, such as nickel-manganese alloy, nickel-cobalt alloy, nickel-palladium, or nickel-tungsten.

In some embodiments, the core material 922 can be formed from non-conductive material, such as silicon core material.

In some embodiments, the inner cladding layer 924 can be formed from conductive material. The conductive material can be copper, silver, gold or alloys thereof.

In some embodiments, the protective layer 926 can be rhodium, gold, platinum, palladium or alloys thereof, and can be formed from conductive metals such as palladium-cobalt alloy, which do not depart from the spirit and scope of the present disclosure.

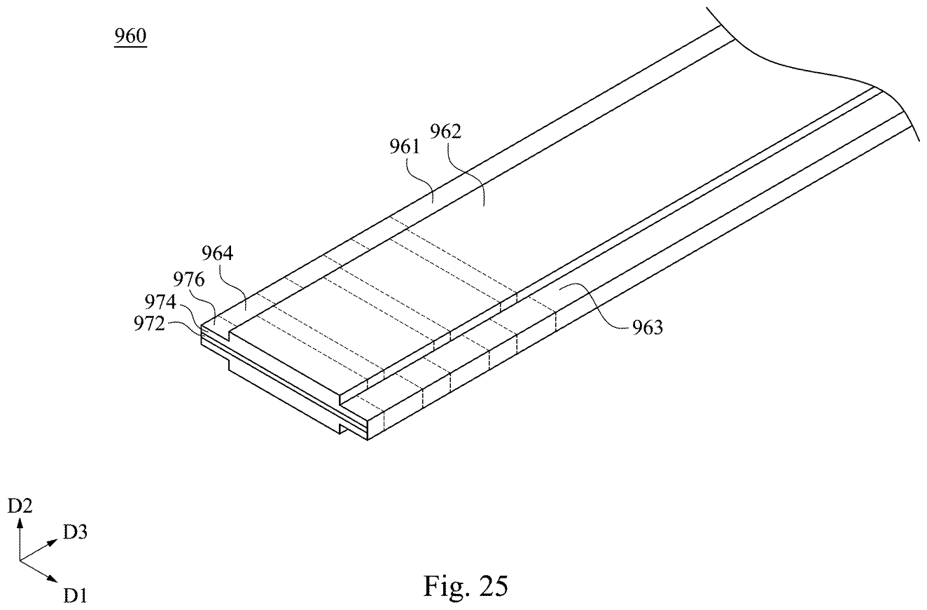

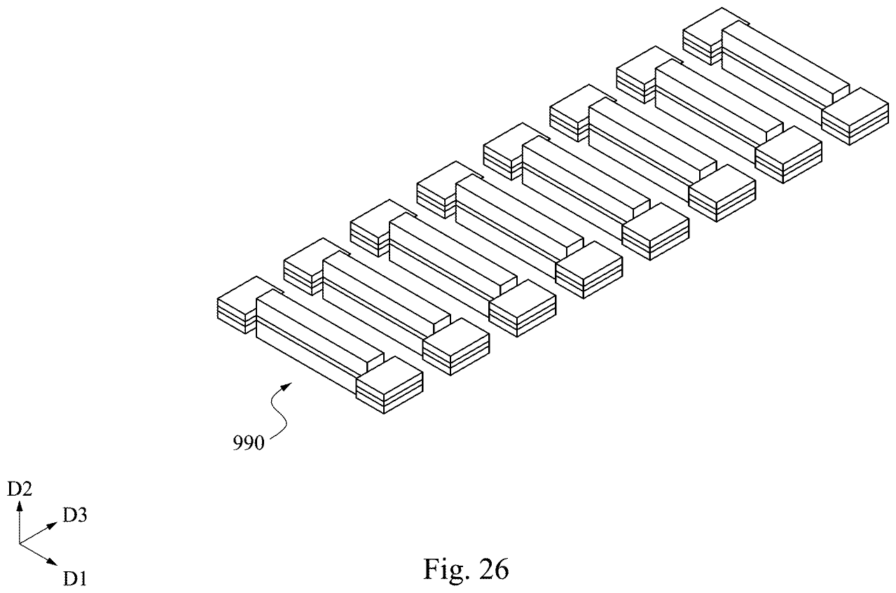

Reference is made to FIGS. 25-26. FIG. 25 is a schematic view of a plate 960 according to a further embodiment of the present disclosure. FIG. 26 is a schematic view of a plurality of finished products 990 cut from the plate 960 of FIG. 25 by laser. As shown in FIGS. 25-26, the plate 960 is formed with recessed portions at the two sides of the first subsidiary plate 961 and the third subsidiary plate 963. Relatively, the second subsidiary plate 962 has a thicker thickness than the first subsidiary plate 961 and the third subsidiary plate 963 in the second direction D2. After being cut along the cutting path 964 by laser, the finished product 990 can be formed, such that the first subsidiary plate 961 is formed as the probe tail of a probe, the second subsidiary plate 962 is formed as the probe body of a probe, and the third subsidiary plate 963 is formed as the probe tip of a probe. The probe is bent around a predetermined direction, such as bending around the second direction D2. The bending direction of the probes can be effectively predetermined and the condition that the probes touch and collide with each other is avoided.

The plate 960 is a composite material plate formed from, for example, a core material 972, an inner cladding layer 974 formed around the core material 972 and a protective layer 976 formed on the surface of the inner cladding layer 974.

In some embodiments, the core material 972 can be formed from nickel, tungsten, cobalt, palladium or alloys thereof, such as nickel-manganese alloy, nickel-cobalt alloy, nickel-palladium, or nickel-tungsten.

In some embodiments, the core material 972 can be formed from non-conductive material, such as silicon core material.

In some embodiments, the inner cladding layer 974 can be formed from conductive material. The conductive material can be copper, silver, gold or alloys thereof.

In some embodiments, the protective layer 976 can be rhodium, gold, platinum, palladium or alloys thereof, and can be formed from conductive metals such as palladium-cobalt alloy, which do not depart from the spirit and scope of the present disclosure.

In conclusion, when compared with the prior art, the aforementioned embodiments of the present disclosure have at least the following advantages:

(1) The user can carry out laser cutting to the plate of different thicknesses. Through the simple and convenient method of laser cutting, the user can produce a finished product from the plate through laser cutting. By repeating the procedures as mentioned above, the user can efficiently produce a plurality of finished products from the plate through laser cutting. In this way, the production of the probes become more efficient and the cost is effectively reduced.

(2) Through the combination of the processing methods of non-laser cutting and the technique of laser cutting, the probes can be manufactured in a simple and easy manner. In addition, the application of laser cutting can decrease the error rate of processing between the probes.

(3) Since the distance between the third paths of laser cutting is larger than the second thickness of the plate, each of the finished products has a side surface in a “+” shape. When the two ends of each of the finished products are compressed towards each other, the central portion tends to bend about the predetermined direction. In this way, when a plurality of finished products are used as probes to be installed at the probe head, and the two ends of each of the finished products are compressed towards each other at the same time, the finished products will bend about the predetermined direction, such that the condition that the probes touch with each other because of bending due to compression is avoided.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A method for manufacturing probes, the method comprising:
forming at least one recessed portion on a plate such that the plate has a first subsidiary plate, a second subsidiary plate and a third subsidiary plate mutually connected along a first direction, the first subsidiary plate having a first thickness along a second direction, the second direction being perpendicular to the first direction, the second subsidiary plate corresponding to the recessed portion and having a second thickness along the second direction, the first thickness being larger than the second thickness, the second subsidiary plate being located between the first subsidiary plate and the third subsidiary plate, the third subsidiary plate having a third thickness along the second direction, the third thickness being larger than the second thickness;
holding the plate;
cutting the plate by laser; and
forming a plurality of probes, wherein each of the probes comprises a probe tail formed from the first subsidiary plate, a probe body formed from the second subsidiary plate and a probe tip formed form the third subsidiary plate, and a width of the probe body along a third direction is larger than a width of the probe tip and the probe tail along the third direction, the third direction being perpendicular to the first direction and the second direction.

2. The manufacturing method of claim 1, wherein forming the recessed portion on the plate comprises:
covering a photoresist material on the plate;
wet etching the plate to remove a portion of the plate such that the plate forms the recessed portion; and
removing the photoresist material.

3. The manufacturing method of claim 1, wherein forming the recessed portion on the plate comprises:
removing a portion of the plate by mechanical cutting such that the plate forms the recessed portion.

4. The manufacturing method of claim 3, wherein the mechanical cutting is milling.

5. The manufacturing method of claim 1, wherein forming the recessed portion on the plate comprises:
sand blasting a surface of the plate such that the plate forms the recessed portion.

6. The manufacturing method of claim 5, wherein the width of the probe tail along the third direction is the same as the width of the probe tip along the third direction.

7. The manufacturing method of claim 5, wherein the width of the probe tail along the third direction is different from the width of the probe tip along the third direction.

8. The manufacturing method of claim 1, wherein cutting the plate by laser comprises:
cutting the second subsidiary plate of the plate along a curved path by laser.

9. The manufacturing method of claim 1, wherein the plate is a composite material plate formed from a core material, an inner cladding layer and a protective layer.

10. The manufacturing method of claim 1, wherein the recessed portion is formed at two sides of the second subsidiary plate.

11. A method for manufacturing probes, the method comprising:
forming a plurality of recessed portions on a plate such that the plate has a first subsidiary plate, a second subsidiary plate and a third subsidiary plate mutually connected along a first direction, the first subsidiary plate having a first thickness along a second direction, the second direction being perpendicular to the first direction, the first subsidiary plate and the third subsidiary plate respectively corresponding to the recessed portions, the second subsidiary plate having a second thickness along the second direction, the second thickness being larger than the first thickness, the second subsidiary plate being located between the first subsidiary plate and the third subsidiary plate, the third subsidiary plate having a third thickness along the second direction, the third thickness being smaller than the second thickness;
holding the plate;
cutting the plate by laser; and
forming a plurality of probes, wherein each of the probes comprises a probe tail formed from the first subsidiary plate, a probe body formed from the second subsidiary plate and a probe tip formed form the third subsidiary plate.

12. The manufacturing method of claim 11, wherein cutting the plate by laser comprises:
cutting the second subsidiary plate of the plate along a curved path by laser.

13. The manufacturing method of claim 11, wherein a width of the probe body along a third direction is equal to a width of the probe tip and the probe tail along the third direction, and the third direction is perpendicular to the first direction and the second direction.

14. The manufacturing method of claim 11, wherein a width of the probe body along a third direction is smaller than a width of the probe tip and the probe tail along the third direction, and the third direction is perpendicular to the first direction and the second direction.

15. The manufacturing method of claim 11, wherein forming the recessed portions on the plate comprises:
covering a photoresist material on the plate;
wet etching the plate to remove a portion of the plate such that the plate forms the recessed portions; and
removing the photoresist material.

16. The manufacturing method of claim 11, wherein forming the recessed portions on the plate comprises:
removing a portion of the plate by mechanical cutting such that the plate forms the recessed portions.

17. The manufacturing method of claim 16, wherein the mechanical cutting is milling.

18. The manufacturing method of claim 11, wherein forming the recessed portions on the plate comprises:
sand blasting a surface of the plate such that the plate forms the recessed portions.

19. The manufacturing method of claim 11, wherein the plate is a composite material plate formed from a core material, an inner cladding layer and a protective layer.

20. The manufacturing method of claim 11, wherein the recessed portions are formed at two sides of the second subsidiary plate.
